(19) United States
(12) Patent Application Publication
(10) Pub. No.: US 2006/0164816 A1
(43) Pub. Date: Jul. 27, 2006

(54) Name card-like disk structure

(76) Inventor: Alex Deng, Taipei County (TW)

Correspondence Address: BACON & THOMAS, PLLC, 625 SLATERS LANE, FOURTH FLOOR, ALEXANDRIA, VA, 22314, US

(21) Appl. No.: 11/042,095

(22) Filed: Jan. 26, 2005

(51) Int. Cl. H05K 1/14

(52) U.S. Cl. 361/737

(57) ABSTRACT

A name card-like disk structure mainly consists of a box, a memory and an extending inserting structure whereby the box is in form of a name card integrated with a memory and an extending inserting structure, designed with a sliding button and a LED indicator at the outer side edge section, and an integrated slot and a hollow curve of the extending inserting structure is pre-designed at the side surface; the memory is thin and is positioned inside the box and is separately connected to one side to the LED indicator and the extending inserting structure; the extending inserting structure is an extending wire but the end is the inserting part and can be re-placed inside the integrated slot or be directly pressed inside the side edge of the box. Hence, the name card-like disk structure is easy to bring along and can be inserted to computers.

### BACKGROUND OF THE INVENTION

1. Field of the invention

The present invention relates to a name card-like disk structure, more specifically to one in the form of a name card installed with a memory and an extending inserting structure.

2. Description of the Related Art

Commonly used portable hard disks such as portable cards and pen-like disks are small in sizes and although they are convenient to carry along, they are occasionally left behind and forgotten and therefore, much improvement is needed in order to avoid disclosure of important documents.

According to the Pat. No. US 2004/0139279 A1 said “the U.S. Pat. No. 6,567,273 is a memory device that has some drawbacks, including that it can be easily damaged or dirt and would cause malfunctioning.” However, the Pat. No. US 2004/0139279 A1 can't really solve the problems because the USB connectors are still accessible from the outside. Furthermore, the Pat. No. US 2004/0139279 A1 is like the shape of name card while the range it can be used is limited, for the reason that USB connectors are both sides and the surface can't be complete.

The object of the invention is name card-like disk structure, in which the drawbacks of the known memory device are eliminated because the USB connector is in the box, and it won't be influenced by the dirt and can be protected better. In addition, for the reason that the surface of the device is flat plane and slippery, it can have some other functions for example, to print some advertisements on or attach the thin calculator on one side.

### SUMMARY OF THE INVENTION

The present invention relates to a name card-like disk structure mainly consisting of a box body, a memory and an extending inserting structure whereby the box body is in form of a name card integrated with a memory and an extending inserting structure, and designed with a LED indicator at the outer side edge section and an integrated slot and a hollow curve of the extending inserting structure is pre-designed at the side edge surface.

The present invention relates to a name card-like disk structure mainly consisting of a box body, a memory and an extending inserting structure whereby the memory is thin and positioned inside the box body and connected separately to one side to the LED indicator and extending inserting body.

The present invention relates to a name card-like disk structure mainly consisting of a box body, a memory and an extending inserting structure whereby the extending inserting structure is an extending wire but the end is the inserting part and can be re-placed inside the integrated slot or be directly pressed inside the side edge of the box.

### A BRIEF DESCRIPTION OF DRAWINGS

FIG. 1 shows a view 1 of the present invention.

FIG. 2 shows a view 2 of the present invention.

FIG. 3 shows a view of the box body structure.

FIG. 4 shows a plan of the inner electrical devices of the upper shell surface.

### DETAIL DESCRIPTION OF THE INVENTION

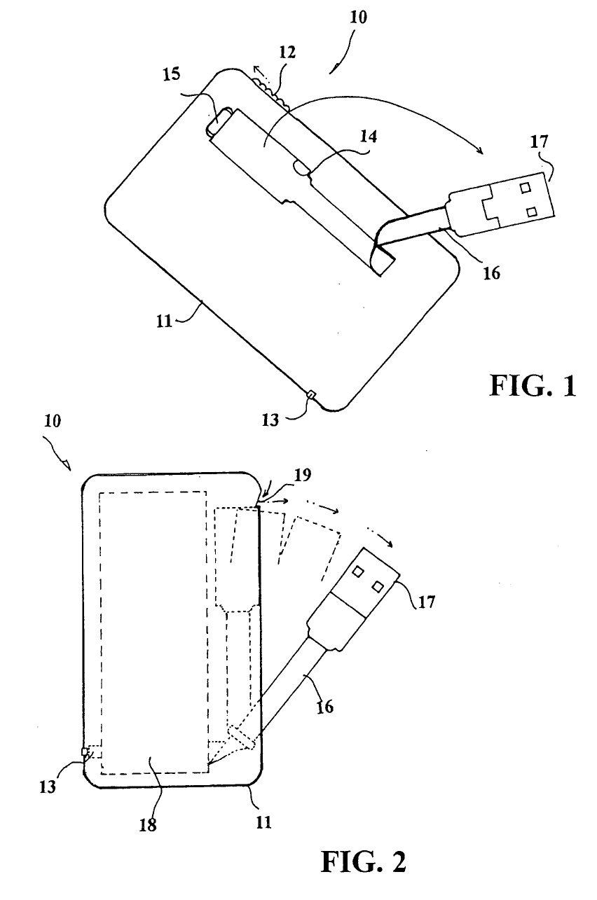

With reference to FIG. 1 showing a view of the present invention, said hard disk 10 is in form of a name card box body 11 in the same size but a sliding button 12 and a LED indicator 13 are designed at the outer side edge section and the hollow curve 15 found at the top of the integrated slot 14 is easily raised by simply lifting the part parallel to the inner extending inserting structure 16. However, the sliding button has to be first activated such that the extending inserting structure can be pulled out and hence, the structure is only convenient for a certain limit of computers' users wherein the inserting plug 17 has to be connected to the U.S.B port.

With reference to FIG. 2 showing a view 2 of the present invention, said hard disk 10 is in form of a name card box body 11 and with the help of the prospective illustration, we can understand that the memory 18 and the extending inserting structure 16 are being directly pressed and securely integrated inside the side edge of the box body 11. However, when in use, the extending inserting structure 16 can be easily pulled out from the opening gap 19 found at the outer side edge section.

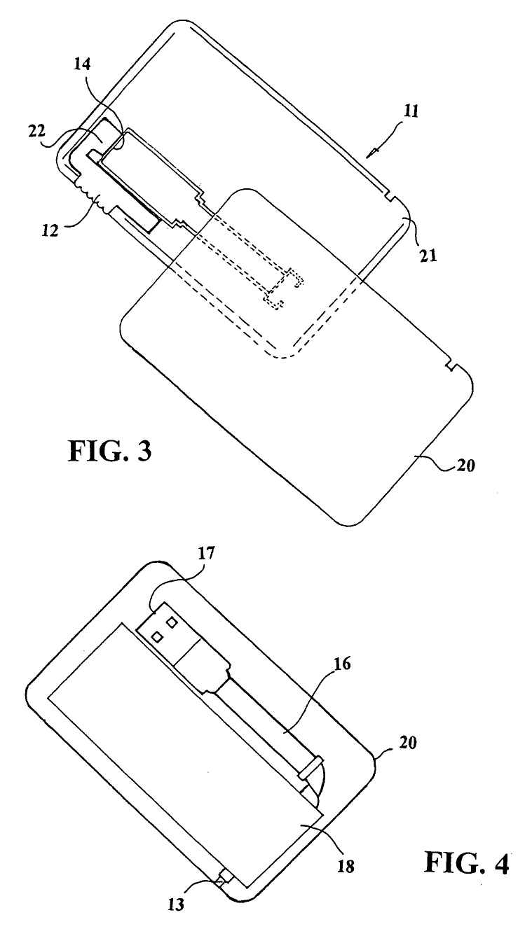

With reference to FIG. 3 showing a view of the box body, said box body 11 relates to the box body structure shown in FIG. 1 and has two shells surface. The upper shell surface 20 refers to a complete surface and can be used for publicity and printing purposes complete shells as shown in diagram 2). The lower shell 21 is designed with an integrated slot 14 and a L-like sliding button 12, an axe-like piece 22 is designed at the front section of the sliding button 12 and can be pulled out or inserted in the opening of the inserting head 17 found at the end section of the extending inserting structure 16 (please refer back to FIGS. 1 and 4), and secured and re-placed in the extending inserting structure 16 and the integrated slot 14.

With reference to FIG. 4 showing a plan of the inner electrical devices of the upper shell, the upper shell surface 20 is turned over and we can clearly notice the memory 18, the LED indicator 13 separately connected at one side and the extending inserting structure 16.

In addition, the hard disk is in the form of a name card and the side edge surface can be used for publicity purposes such as practical gifts or it can also be used as employees' identifying name tags by simply inserting a transparent name tag hanger.

1. A kind of “name card-like disk structure” mainly consisting of a box body, a memory and an extending inserting structure, wherein:
said box body is inform of a name card and is integrated with a memory and an extending inserting structure and a sliding button and LED indicator are designed at the outer side edge section, and an integrated slot and a hollow curve of the extending inserting structure is also pre-designed at the side edge surface;
said memory is thin and positioned inside the box body and is separately connected at one side to the LED indicator and extending inserting body;
said extending inserting structure is an extending wire but the end is the inserting part and can be replaced inside the integrated slot, as characterized.

2. As mentioned in claim 1 of a “name card-like disk structure”, said extending inserting structure can be directly pressed and integrated inside the side edge of the box body and the side edge surface is no longer provided with a hollow curve but an opening gap is designed at a section of the outer side edge such as to substitute the sliding button in order to facilitate pulling out of the extending inserting structure.

3. As mentioned in claim 1 of a “name card-like disk structure”, said sliding button is in form of a L and is provided with an axe-like piece and can be easily pulled out or inserted into the opening of the inserting head such as to re-place and secure the extending inserting structure in the integrated slot.
